(19) United States
(12) Patent Application Publication
(10) Pub. No.: US 2026/0056378 A1
(43) Pub. Date: Feb. 26, 2026

(54) OPTICAL MODULE INCLUDING HEAT SINK AND LIQUID COOLING PIPE

(71) Applicant: Prime World International Holdings Ltd., New Taipei City (TW)

(72) Inventors: Che-Shou YEH, New Taipei City (TW); Ming-You LAI, New Taipei City (TW); Hsuan-Chen SHIU, New Taipei City (TW); YI-JU WANG, New Taipei City (TW); Ling-An KUNG, New Taipei City (TW)

(21) Appl. No.: 18/954,333

(22) Filed: Nov. 20, 2024

(30) Foreign Application Priority Data
Aug. 21, 2024 (TW) 113131455

(51) Int. Cl. G02B 6/42; H05K 7/20

(52) U.S. Cl. CPC G02B 6/4269; G02B 6/4261; H05K 7/20263

(57) ABSTRACT

The present disclosure provides an optical module, including a housing, a heat sink, and a liquid cooling pipe. The heat sink is coupled to an outer surface of the housing. The liquid cooling pipe is coupled to the outer surface or an inner surface of the housing, the liquid cooling pipe has at least one pipe joint, and an opening of the at least one pipe joint is proximate to an electrical port of the optical module.

### CROSS-REFERENCE TO RELATED APPLICATIONS

This non-provisional application claims priority under 35 U.S.C. § 119(a) on Patent Application No(s). 113131455 filed in Taiwan, ROC on Aug. 21, 2024, the entire contents of which are hereby incorporated by reference.

### BACKGROUND

### Technical Field

The present disclosure relates to an optical module.

### Related Art

Optical modules can transmit and/or receive optical signals for various applications including, but not limited to, internet data center, Cable TV, and fiber to the home (FTTH). Using optical modules for transmission can provide higher transmission rates and signal bandwidth over longer transmission distances. In order to enhance the compatibility of optical internetworking products all over the world and to reduce the burden of maintenance, organizations such as Multi-Source Agreement (MSA), Institute of Electrical and Electronic Engineers (IEEE), and Optical Internetworking Forum (OIF) have developed several form factors adapted to different signal transmission rates. These form factors include, but not limited to, XFP, SFP, QSFP (Quad Small Form Factor Pluggable), QSFP-DD (Double Density), OSFP (Octal Small Form Factor Pluggable), and CPO (Co-Packaged Optics).

However, conventional optical modules still present some problems, such as optical power, space management, thermal management, insertion loss, and manufacturing yield.

### SUMMARY

According to one embodiment of the present disclosure, an optical module includes a housing, a heat sink, and a liquid cooling pipe. The heat sink is coupled to an outer surface of the housing. The liquid cooling pipe is coupled to the outer surface or an inner surface of the housing, the liquid cooling pipe has at least one pipe joint, and an opening of the at least one pipe joint is proximate to an electrical port of the optical module.

According to one embodiment of the present disclosure, an optical module includes a housing and a liquid cooling pipe. The liquid cooling pipe is coupled to an outer surface of the housing and configured for a liquid coolant to flow therein. The liquid cooling pipe includes at least one pipe joint and a bending part. An optical port and an electrical port of the optical module are disposed along a longitudinal direction. The bending part is disposed closer to the optical port than the at least one pipe joint in the longitudinal direction, and the pipe joint extends out of the electrical port.

### BRIEF DESCRIPTION OF THE DRAWINGS

The present disclosure will become better understood from the detailed description given hereinbelow and the accompanying drawings which are given by way of illustration only and thus are not intended to limit the present disclosure and wherein:

FIG. 1 is a perspective view of an optical module according to an embodiment of the present disclosure;

FIG. 2 is an exploded view of the optical module in FIG. 1;

FIG. 3 is a top view of the optical module in FIG. 1;

FIG. 4 is a schematic view showing that the optical module in FIG. 1 is coupled to an external cooling device;

FIG. 5 is a partially enlarged view showing a state where a liquid cooling pipe of the optical module in FIG. 1 is decoupled from the external cooling device; and

FIG. 6 is a partially enlarged view showing that the optical module in FIG. 1 is coupled to the external cooling device.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

The thermal management of an optical module mainly relates to transferring the heat generated by components to a housing to dissipate the heat to the outside. The power consumption of the optical module is increased with the demand for high-speed optical communications, requiring higher heat dissipation efficiency. Disposing or forming heat dissipation fins on a housing of an optical module is one of the solutions to enhance heat dissipation efficiency. However, such heat dissipation structure thereof is unable to meet the demand for higher heat dissipation efficiency.

According to an embodiment of the present disclosure, a heat sink of the optical module may cool the optical module by air cooling, and the liquid cooling pipe of the optical module and the liquid coolant therein can cool the optical module by direct liquid cooling (DLC). In an optical module known by the inventor that is cooled only by air cooling, the temperature of the housing is about 70° C. In contrast, in an optical module that is cooled by both air cooling and DLC, the temperature of the housing is reduced to be about 50° C. The temperature of the optical module which is cooled by both air cooling and DLC will be lower than that of the optical module which is cooled only by DLC. Therefore, the heat dissipation efficiency of the optical module which is cooled by both air cooling and direct liquid cooling may be enhanced.

Some or all of the technical features disclosed in one or more embodiments of the present disclosure may be combined to achieve corresponding effects.

The term “couple” or “coupled to” refers to any connection, link, or the like. Moreover, the term “optically couple” or “optically coupled to” refers to a relationship where light is transmitted (imparted) from a device to another. Unless otherwise specified, devices that “couple” or “coupled to” each other do not need to be directly coupled to each other and may be separated by intervening objects.

The term substantially, as generally referred to herein, refers to a degree of precision within acceptable tolerance that accounts for and reflects minor real-world variation due to material composition, material defects, and/or limitations/peculiarities in manufacturing processes. Such variation may therefore be said to achieve largely, but not necessarily wholly, the stated characteristic.

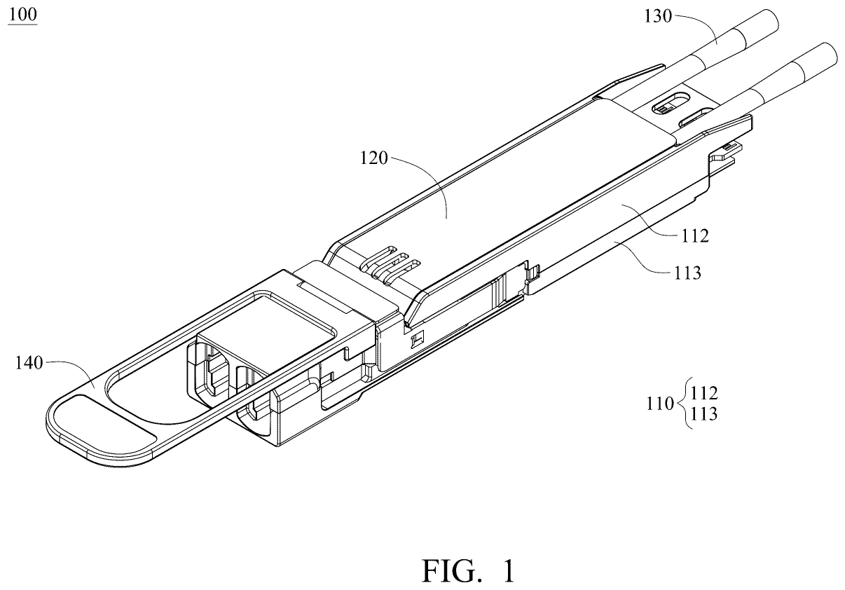

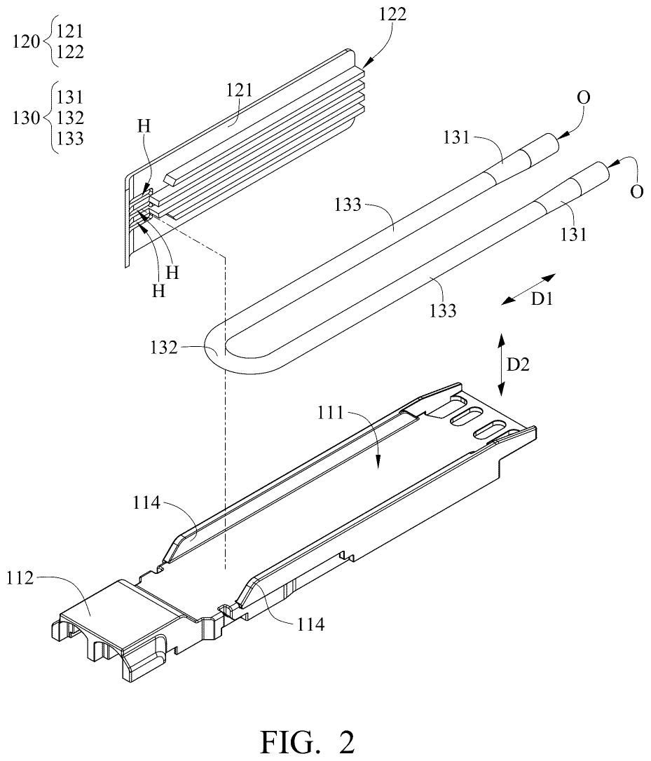

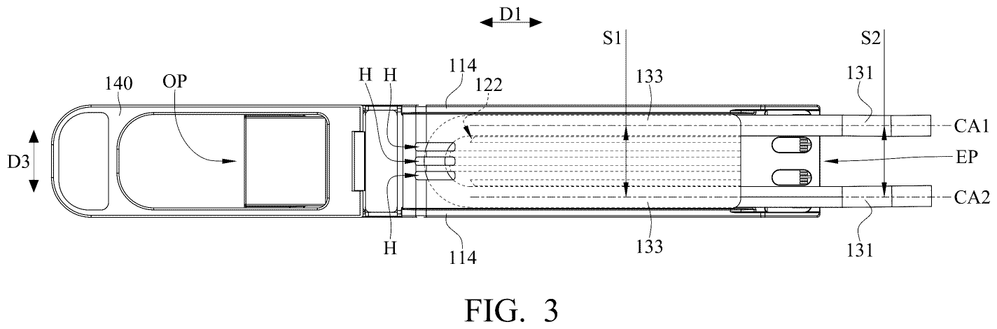

FIG. 1 is a perspective view of an optical module 100 according to an embodiment of the present disclosure, FIG. 2 is an exploded view of the optical module 100 in FIG. 1, and FIG. 3 is a top view of the optical module 100 in FIG. 1. According to one embodiment, the optical module 100 may be, for example, an Octal Small Form Factor Pluggable (OSFP) optical module, but the present disclosure is not limited thereto. According to one embodiment, the optical module 100 may include a housing 110, a heat sink 120, and a liquid cooling pipe 130 configured for a liquid coolant to flow therein.

In one embodiment, the housing 110 may be made of a thermally conductive material, such as metal. According to one embodiment, the housing 110 may accommodate a printed circuit board assembly (PCBA) and one or more optical communication components coupled to the PCBA. For example, the optical communication components may include, but not limited to, at least one of a transmitting optical sub-assembly (TOSA) and a receiver optical sub-assembly (ROSA). In one embodiment, the optical communication component includes a TOSA. In one embodiment, the optical communication component includes a ROSA. In one embodiment, the optical communication component includes both of a TOSA and a ROSA. In one embodiment, the optical communication components in the optical module 100 may be thermally coupled to the housing 110 such that the heat generated by the optical communication components can be effectively transferred to the thermal conductive housing 110.

The heat sink 120 may be coupled to an outer surface 111 of the housing 110 to allow the heat to be effectively transferred from the housing 110 to the heat sink 120. The liquid cooling pipe 130 may be coupled to the housing 110 to allow the heat to be effectively transferred from the housing 110 to the liquid cooling pipe 130. In one embodiment, as shown in FIG. 2, the outer surface 111 is an exposed top surface of the housing 110. The liquid cooling pipe 130 may have at least one pipe joint 131. An opening O of the pipe joint 131 may be proximate to an electrical port EP of the optical module 100. In one embodiment, the liquid cooling pipe 130 may be welded or soldered to the housing 110. According to one embodiment, the electrical port EP may accommodate a transmit connecting circuit or a receiver connecting circuit coupled to the PCBA.

According to one embodiment, the housing 110 may be a multi-part housing including an upper housing part 112 and a lower housing part 113 which are coupled to each other, and both of the heat sink 120 and the liquid cooling pipe 130 may be coupled to the upper housing part 112. An optical port OP and the electrical port EP of the optical module 100 may be disposed along a longitudinal direction D1, the upper housing part 112 may have two protrusions 114 that extend along a vertical direction D2 substantially perpendicular to the longitudinal direction D1, and the liquid cooling pipe 130 may be disposed between the two protrusions 114. In one embodiment, the housing 110 may be formed as a single piece. According to one embodiment, the optical port OP may accommodate an optical fiber connector.

According to one embodiment, the optical module 100 may further include a pull tab 140 disposed on the housing 110. In one embodiment, as shown in FIG. 1, the pull tab 140 may be disposed on the upper housing part 112. For illustration purposes, the lower housing part 113 and the pull tab 140 are omitted from FIG. 2.

According to one embodiment, the heat sink 120 may include a cover body 121 and a plurality of fins 122. The fins 122 are coupled to the cover body 121, and the cover body 121 may be coupled to the housing 110 and cover the liquid cooling pipe 130. In one embodiment, the cover body 121 may be integrally formed as a single piece with the fins 122.

According to one embodiment, the optical port OP and the electrical port EP of the optical module 100 may be disposed along the longitudinal direction D1. In one embodiment, the optical port OP has an optical interface including one or more receptacles for optical cable connections. In one embodiment, the electrical port EP is understood as an end of the housing 110 where an opening is formed to expose PCBA or the transmit/receiver connecting circuit.

The liquid cooling pipe 130 may include a bending part 132 and two extending parts 133 that are coupled to bending part 132. The two extending parts 133 may extend along the longitudinal direction D1. The fins 122 may be disposed between the two extending parts 133. The bending part 132 may be disposed closer to the optical port OP than the fins 122 in the longitudinal direction D1. In one embodiment, the at least one pipe joint 131, the bending part 132, and the extending parts 133 of the liquid cooling pipe 130 may be integrally formed as a single piece. In one embodiment, the bending part 132 is disposed closer to the optical port OP than the pipe joint 131 in the longitudinal direction D1.

Referring to FIG. 3, the dimension of the liquid cooling pipe 130 may be designed for optical module compactness. In one embodiment, a distance between centers of the two extending parts 133 is smaller than a traverse size of the housing 110. In one embodiment, a distance S1 between a first central axis CA1 and a second central axis CA2 of the two extending parts 133 is smaller than a size of the housing 110 in a traverse direction D3. In one embodiment, a distance S2 between the first central axis CA1 and the second central CA2 of the pipe joints 131 is smaller than a size of the housing 110 in the traverse direction D3.

According to one embodiment, the cover body 121 may have a plurality of holes H which correspond to the fins 122, and a part of the liquid cooling pipe 130 may be disposed between the plurality of holes H and the fins 122. As shown in FIG. 3, the bending part 132 of the liquid cooling pipe 130 is disposed between the holes H and the fins 122 in the traverse direction D3. According to one embodiment, a cold air may dissipate heat by passing through gaps between adjacent fins 122 via the plurality of holes H.

According to one embodiment, the liquid cooling pipe 130 may be coupled to the outer surface 111 of the housing 110 to prevent the liquid cooling pipe 130 from disturbing the arrangement of the components inside the housing 110. Thus, the arrangement of the components inside the housing 110 is not required to be redesigned. In one embodiment, the liquid cooling pipe 130 is coupled to an inner surface of the housing 110, wherein the inner surface defines at least part of an accommodation space for accommodating aforesaid PCBA and optical communication components. In one embodiment, the liquid cooling pipe 130 is coupled to an inner surface of the upper housing part 112 of the housing 110.

According to one embodiment, the liquid cooling pipe 130 and the housing 110 may be separated components. In one embodiment, the liquid cooling pipe 130 is screwed to, adhered to, welded to or soldered to the housing 110. In one embodiment, as shown in FIG. 1, the liquid cooling pipe 130 is welded to the upper housing part 112 of the housing 110. Because the upper housing part 112 may be used as a baseplate where the liquid cooling pipe 130 is coupled, the upper housing part 112 and the liquid cooling pipe 130 can be jointly configured as a liquid cooling plate, such that an additional liquid cooling plate can be omitted, thereby reducing the manufacturing cost of the optical module 100. Also, due to the characteristic of separated components, a liquid cooling plate including the liquid cooling pipe 130 and the housing 110 can be manufactured in a low-cost manner.

According to one embodiment, the number of the at least one pipe joint 131 may be two, the liquid cooling pipe 130 may include a bending part 132 and two extending parts 133 that are coupled to the bending part 132, the two extending parts 133 may have two pipe joints 131, respectively, and the two pipe joints 131 may extend out of the electrical port EP of the optical module 100. According to one embodiment, the pipe joint 131 may be coupled to a liquid cooling pipe 210 of an external cooling device 200. In one embodiment, the pipe joint 131 may be a quick coupler, but the present disclosure is not limited thereto.

According to one embodiment, the optical port OP and the electrical port EP of the optical module 100 may be disposed along the longitudinal direction D1. The outer surface 111 of the housing 110 may be not inclined in the longitudinal direction D1 (i.e., the normal direction of the 111 may be perpendicular to the longitudinal direction D1), and thus the manufacturing cost of the optical module 100 is reduced and the specification of the optical module 100 may be easily meet. Also, a heat liquid cooling pipe (not shown) may be disposed on the housing 110 of the optical module 100. In this embodiment, because the external cooling device that is coupled to the liquid cooling pipe 130 may be able to drive the liquid coolant to circulate between the external cooling device and the liquid cooling pipe 130, the outer surface 111 may not need to be inclined in the longitudinal direction. In other embodiments, in order to allow the working fluid inside the heat liquid cooling pipe to flow by natural convection, the housing of the optical module may be inclined in the longitudinal direction.

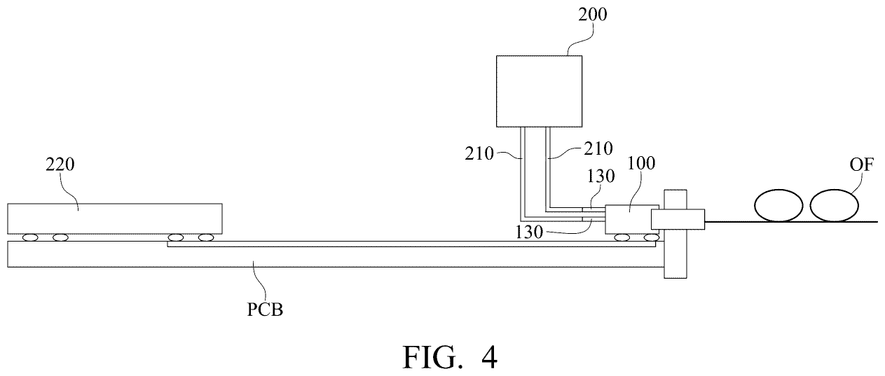

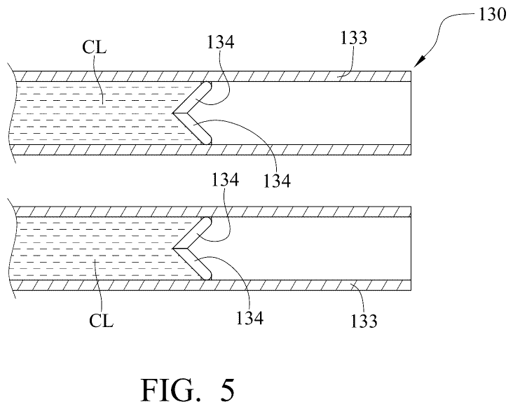

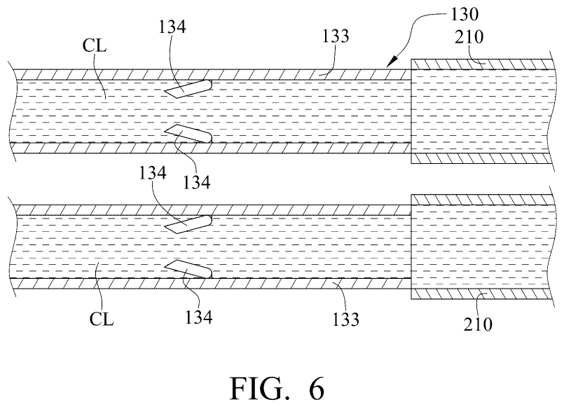

FIG. 4 is a schematic view showing that the optical module 100 in FIG. 1 is coupled to an external cooling device 200, FIG. 5 is a partially enlarged view showing a state where the liquid cooling pipe 130 of the optical module 100 in FIG. 1 is decoupled from the external cooling device 200, and FIG. 6 is a partially enlarged view showing that the optical module 100 in FIG. 1 is coupled to the external cooling device 200.

Please refer to FIG. 4. According to one embodiment, a host board may be disposed inside a host system such as switch, and the host board may be a printed circuit board. A chip 220 may be disposed on the printed circuit board PCB in a system-on-chip (SoC) manner. In one embodiment, the chip 220 may be, for example, an application specific integrated circuit (ASIC). The printed circuit board PCB may be electrically coupled to the optical module 100. According to one embodiment, the optical module 100 to which an optical cable OF is optically coupled may be thermally coupled to the external cooling device 200 through the liquid cooling pipe 130. In one embodiment, the optical module 100 may be coupled to the external cooling device 200 through the quick coupler (in the form of a joint). In one embodiment, the external cooling device 200 may be located inside the switch. In one embodiment, the external cooling device 200 may be a heat exchanger. In one embodiment, the external cooling device 200 may be a cooling tower. However, the external cooling device 200 is not limited thereto.

Please refer to FIGS. 5 and 6. When the liquid cooling pipe 130 of the optical module 100 is decoupled from the external cooling device 200, a valve 134 in the quick coupler of the liquid cooling pipe 130 will be closed prevent a liquid coolant CL inside the liquid cooling pipe 130 from flowing out of the liquid cooling pipe 130. When the liquid cooling pipe 130 of the optical module 100 is coupled to the liquid cooling pipe 210 of the external cooling device 200, the valve 134 in the quick coupler of the liquid cooling pipe 130 will be opened so that the coolant CL inside the liquid cooling pipe 130 will circulate between 130 and 200. In one embodiment, a flowing direction of the coolant CL in one of the two extending parts 133 of the liquid cooling pipe 130 may be different from a flowing direction of the coolant CL in the other of the two extending parts 133 of the liquid cooling pipe 130.

The coolant CL flowing inside the liquid cooling pipe 130 may cool the optical module 100. Meanwhile, a cold air may cool the optical module 100 by flowing to the electrical port EP through the holes H of the cover body 121.

According to the present disclosure, the heat sink may cool the optical module by air cooling, a cold air may dissipate heat by passing through the holes and the fins by air cooling, and the liquid cooling pipe can cool the optical module by DLC. Therefore, the heat dissipation efficiency of the optical module which is cooled by both air cooling and DLC may be enhanced.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. An optical module, comprising:
a housing;
a heat sink, coupled to an outer surface of the housing; and
a liquid cooling pipe, coupled to the outer surface or an inner surface of the housing and configured for a liquid coolant to flow therein, wherein the liquid cooling pipe comprises at least one pipe joint, and an opening of the at least one pipe joint is proximate to an electrical port of the optical module.

2. The optical module according to claim 1, wherein the housing comprises an upper housing part and a lower housing part which are coupled to each other, and the heat sink and the liquid cooling pipe are coupled to the outer surface of the upper housing part;
wherein, an optical port and the electrical port of the optical module are disposed along a longitudinal direction, the upper housing part comprises two protrusions that extend along a vertical direction substantially perpendicular to the longitudinal direction, and the liquid cooling pipe is disposed between the two protrusions.

3. The optical module according to claim 1, wherein the heat sink comprises a cover body and a plurality of fins, the plurality of fins are coupled to the cover body, and the cover body is coupled to the housing and covers the liquid cooling pipe.

4. The optical module according to claim 3, wherein an optical port and the electrical port of the optical module are disposed along a longitudinal direction, the liquid cooling pipe comprises a bending part and two extending parts that are coupled to the bending part, the two extending parts extend along the longitudinal direction, the plurality of fins are disposed between the two extending parts, and the bending part is disposed closer to the optical port than the plurality of fins in the longitudinal direction.

5. The optical module according to claim 3, wherein the cover body has a plurality of holes which correspond to the plurality of fins, and a part of the liquid cooling pipe is disposed between the plurality of holes and the plurality of fins.

6. The optical module according to claim 1, wherein the liquid cooling pipe and the housing are separated components.

7. The optical module according to claim 1, wherein the at least one pipe joint comprises two pipe joints, the liquid cooling pipe comprises a bending part and two extending parts that are coupled to the bending part, the two extending part has the two pipe joints, respectively, and the two pipe joints extend out of the electrical port of the optical module.

8. The optical module according to claim 1, wherein an optical port and the electrical port of the optical module are disposed along a longitudinal direction, and the outer surface of the housing is not inclined in the longitudinal direction.

9. The optical module according to claim 1, wherein the at least one pipe joint is a quick coupler.

10. The optical module according to claim 1, wherein the optical module is an Octal Small Form Factor Pluggable (OSFP) optical module.

11. An optical module, comprising:
a housing; and
a liquid cooling pipe, coupled to an outer surface or an inner surface of the housing and configured for a liquid coolant to flow therein, wherein the liquid cooling pipe comprises at least one pipe joint and a bending part;
wherein, an optical port and an electrical port of the optical module are disposed along a longitudinal direction, the bending part is disposed closer to the optical port than the at least one pipe joint in the longitudinal direction, and the at least one pipe joint extends out of the electrical port.

12. The optical module according to claim 11, wherein the housing comprises an upper housing part and a lower housing part which are coupled to each other, and the liquid cooling pipe are coupled to the outer surface of the upper housing part;
wherein the upper housing part comprises two protrusions that extend along a vertical direction substantially perpendicular to the longitudinal direction, and the liquid cooling pipe is disposed between the two protrusions.

13. The optical module according to claim 11, further comprising a heat sink coupled to the housing, wherein the heat sink comprises a cover body and a plurality of fins, the plurality of fins are coupled to the cover body, and the cover body is coupled to the housing and covers the liquid cooling pipe.

14. The optical module according to claim 11, wherein the liquid cooling pipe and the housing are separated components.

15. The optical module according to claim 11, wherein the at least one pipe joint comprises two pipe joints, the liquid cooling pipe further comprises two extending parts coupled to the bending part, the two extending part extend along the longitudinal direction and has the two pipe joints, respectively, and the two pipe joints extend out of the electrical port of the optical module.

16. The optical module according to claim 15, wherein a distance between centers of the two extending parts is smaller than a size of the housing in a traverse direction.

17. The optical module according to claim 11, wherein the optical module is an Octal Small Form Factor Pluggable (OSFP) optical module.
